(19) United States
(12) Patent Application Publication
(10) Pub. No.: US 2023/0120674 A1
(43) Pub. Date: Apr. 20, 2023

(54) TRANSISTOR DRIVE CIRCUIT

(71) Applicant: ROHM CO., LTD., Kyoto (JP)

(72) Inventor: Asuma IMAMURA, Kyoto (JP)

(73) Assignee: ROHM CO., LTD., Kyoto (JP)

(21) Appl. No.: 17/913,979

(22) PCT Filed: Mar. 16, 2021
(86) PCT No.: PCT/JP2021/010656

§ 371 Date: Sep. 23, 2022

(30) Foreign Application Priority Data
Mar. 27, 2020 (JP) 2020-058191

(51) Int. Cl. H03K 17/16; H02M 1/08; H02M 1/00

(52) U.S. Cl. CPC H03K 17/165; H02M 1/08; H02M 1/0054; H02M 1/0029; H02M 3/158

(57) ABSTRACT

Provided is a transistor drive circuit that drives a transistor to be driven and has a configuration including a controller that performs control to cause to temporally vary a circuit parameter contributing to a rise time or a fall time of the transistor to be driven.

### TECHNICAL FIELD

The invention disclosed in the present description relates to a transistor drive circuit.

### BACKGROUND ART

It is conventionally known that in a transistor such as a MOSFET (a MOS transistor), during switch-driving of the transistor, EMI (electromagnetic interference) noise might occur due to a high-frequency component of an output voltage (Vds (a drain-source voltage) in a case of the MOSFET) of the transistor.

Known switching characteristics of such a transistor include a rise time tr and a fall time tf of an output voltage of the transistor. In a case where the transistor is, for example, a MOSFET, as shown in FIG. 10, the rise time tr is defined as a time taken for Vds to rise from 10% to 90%, and the fall time tf is defined as a time taken for Vds to fall from 90% to 10%.

The EMI noise is increased when the rise time tr and the fall time tf are short and is reduced when the rise time tr and the fall time tf are long. Meanwhile, switching loss is reduced when the rise time tr and the fall time tf are decreased and is increased when the rise time tr and the fall time tf are increased. In this manner, the EMI noise and the switching loss (power loss) are in a trade-off relationship.

### CITATION LIST

### Patent Literature

Patent Document 1: JP-A-2014-165890

### SUMMARY OF INVENTION

### Technical Problem

Herein, Patent Document 1 discloses a load drive control device intended to reduce both of the EMI noise and the switching loss. In Patent Document 1 described above, a capacitance is connected to an input side of a pre-driver that drives an NMOS transistor and is charged or discharged so that an output voltage of the pre-driver varies, and the NMOS transistor is turned on/off by the output voltage of the pre-driver so as to obtain linear rising and falling gradients of Vds of the NMOS transistor. Accordingly, it is possible to reduce the power loss at a time of turning on/off the NMOS transistor to a minimum amount of loss required for a high-frequency region characteristic of the EMI noise and thus to reduce the switching loss as well as the EMI noise.

Patent Document 1 described above, however, has been disadvantageous in that the rise time tr and the fall time tf of the transistor each occur in a temporally uniform manner, so that an obtained effect of reducing the EMI noise and the switching loss might be insufficient.

In view of the above-described circumstances, an object of the invention disclosed in the present description is to provide a transistor drive circuit capable of reducing EMI noise while suppressing an increase in switching loss.

### Solution to Problem

An aspect of the invention disclosed in the present description is a transistor drive circuit that drives a transistor to be driven and includes a controller that performs control to cause to temporally vary a circuit parameter contributing to a rise time or a fall time of the transistor to be driven (a first configuration).

Furthermore, in the above-described first configuration, the circuit parameter may be a current that is supplied to a control terminal of the transistor to be driven (a second configuration).

Furthermore, in the above-described second configuration, there may be further provided a pre-driver that includes a first transistor portion through which the current flows, and the controller may cause to temporally vary an on-resistance of the first transistor portion (a third configuration).

Furthermore, in the above-described third configuration, the first transistor portion may include a plurality of first transistors that are connected in parallel between an application terminal of a power supply voltage and the control terminal, and the controller may cause to temporally vary the number of parallel connected first transistors that are in an enabled state and capable of being turned on/off among the plurality of first transistors (a fourth configuration).

Furthermore, in the above-described fourth configuration, each of the first transistors may be a PMOS transistor, and the pre-driver may include a first switch that is disposed between an application terminal of a gate signal and a gate of the each of the first transistors and a second switch that is disposed between the gate and a source of the each of the first transistors (a fifth configuration).

Furthermore, in the above-described first configuration, the circuit parameter may be a current drawn out of a control terminal of the transistor to be driven (a sixth configuration).

Furthermore, in the above-described sixth configuration, there may be further provided a pre-driver that includes a second transistor portion through which the current flows, and the controller may cause to temporally vary an on-resistance of the second transistor portion (a seventh configuration).

Furthermore, in the above-described seventh configuration, the second transistor portion may include a plurality of second transistors that are connected in parallel between the control terminal and an application terminal of a reference potential, and the controller may cause to temporally vary the number of parallel connected second transistors that are in an enabled state and capable of being turned on/off among the plurality of second transistors (an eighth configuration).

Furthermore, in the above-described eighth configuration, each of the second transistors may be an NMOS transistor, and

the pre-driver may include a third switch that is disposed between an application terminal of a gate signal and a gate of the each of the second transistors and a fourth switch that is disposed between the gate and a source of the each of the second transistors (a ninth configuration).

Furthermore, in the above-described first configuration, the circuit parameter may be a feedback capacitance of the transistor to be driven (a tenth configuration).

Furthermore, in the above-described tenth configuration, the controller may cause to temporally vary the number of parallel connected feedback capacitances including a first feedback capacitance as a parasitic capacitance of the transistor to be driven and an enabled one of at least one second feedback capacitance other than the first feedback capacitance (an eleventh configuration).

Furthermore, in the above-described eleventh configuration, the controller may control a fifth switch for switching between enabled and disabled states of the at least one second feedback capacitance (a twelfth configuration).

Furthermore, in the above-described third configuration, the first transistor portion may include a PMOS transistor, and the controller may cause to temporally vary a power supply voltage of the pre-driver (a thirteenth configuration).

Furthermore, in the above-described thirteenth configuration, the power supply voltage may be a boot voltage generated by a bootstrap (a fourteenth configuration).

Furthermore, in the above-described fourteenth configuration, the controller may cause to temporally vary a voltage that is applied to an anode of a diode included in the bootstrap (a fifteenth configuration).

Furthermore, another aspect of the invention disclosed in the present description is a switching circuit including the transistor drive circuit of any of the above-described configurations and the transistor to be driven (a sixteenth configuration).

Furthermore, in the above-described sixteenth configuration, the transistor to be driven may be an NMOS transistor (a seventeenth configuration).

Furthermore, the above-described seventeenth configuration may further include an NMOS transistor on a low potential side that is connected in series with the transistor to be driven on a high potential side (an eighteenth configuration).

Furthermore, still another aspect of the invention disclosed in the present description is a switching power supply circuit including the switching circuit of any of the above-described configurations.

### Advantageous Effects of Invention

According to the transistor drive circuit disclosed in the present description, it is possible to reduce EMI noise while suppressing an increase in switching loss.

### BRIEF DESCRIPTION OF DRAWINGS

FIG. 1 is a diagram showing a configuration of a DC/DC converter according to an illustrative embodiment of the present invention.

FIG. 2 is a diagram showing a partial configuration of a transistor drive circuit according to a first embodiment of the present invention.

FIG. 3 is a diagram showing a partial configuration of a transistor drive circuit according to a second embodiment of the present invention.

FIG. 4 is a diagram showing a partial configuration of a transistor drive circuit according to a third embodiment of the present invention.

FIG. 5 is a diagram showing a partial configuration of a transistor drive circuit according to a fourth embodiment of the present invention.

FIG. 6 is a diagram showing a configuration of a DC/DC converter according to a fifth embodiment of the present invention.

FIG. 7 is a diagram showing a configuration of a DC/DC converter according to a sixth embodiment of the present invention.

FIG. 8 is a diagram showing a configuration of a DC/DC converter according to a seventh embodiment of the present invention.

FIG. 9 illustrates graphs showing an example of a result of an FFT analysis performed on a ripple waveform of an input voltage.

FIG. 10 is a diagram for explaining a rise time and a fall time of a MOSFET.

### DESCRIPTION OF EMBODIMENTS

With reference to the appended drawings, the following describes an illustrative embodiment of the present invention.

### Configuration of DC/DC Converter

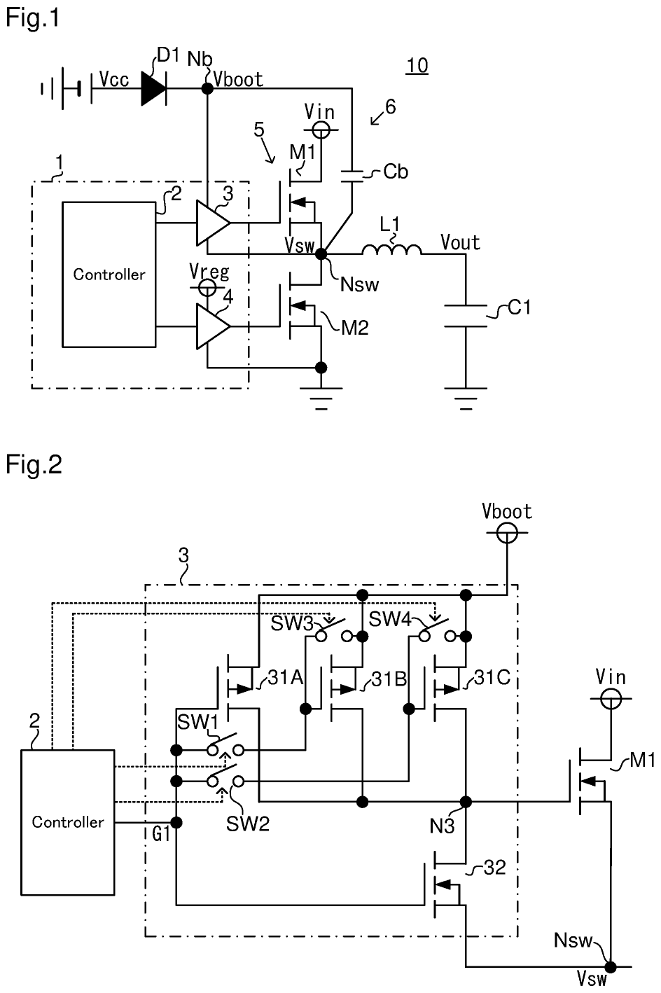

FIG. 1 is a diagram showing a configuration of a DC/DC converter 10 according to the illustrative embodiment of the present invention. The DC/DC converter 10 is a step-down converter that steps down an input voltage Yin to generate an output voltage Vout.

As shown in FIG. 1, the DC/DC converter 10 includes a switching circuit 5, an inductor L1, an output capacitor C1, a boot capacitor Cb, and a diode D1.

The switching circuit 5 includes a transistor drive circuit 1, an NMOS transistor M1, and an NMOS transistor M2. The NMOS transistor M1 and the NMOS transistor M2 are to be switch-driven by the transistor drive circuit 1.

The NMOS transistor M1 and the NMOS transistor M2 are connected in series between an application terminal of the input voltage Yin and an application terminal of a ground potential so as to form a bridge. Specifically, a drain of the NMOS transistor M1 is connected to the application terminal of the input voltage Vin. A source of the NMOS transistor M1 is connected at a node Nsw to a drain of the NMOS transistor M2. A source of the NMOS transistor M2 is connected to the application terminal of the ground potential. That is, the NMOS transistor Ml is a high-side transistor on a high potential side, and the NMOS transistor M2 is a low-side transistor on a low potential side.

One end of the inductor L1 is connected to the node Nsw. The other end of the inductor L1 is connected to one end of the output capacitor C1. The other end of the output capacitor C1 is connected to an application terminal of the ground potential. The output voltage Vout is generated at the one end of the output capacitor C1.

The NMOS transistor M1 and the NMOS transistor M2 are complementarily switch-driven so that when one of them is in an on-state, the other is in an off-state. Such complementary switch-driving also includes a case where a dead time is provided during which both of them are placed in the off-state for the purpose of, for example, preventing the occurrence of a through current.

One end of the boot capacitor Cb is connected to the node Nsw. The other end of the boot capacitor Cb is connected to a cathode of the diode D1. A power supply voltage Vcc is applied to an anode of the diode D1. The boot capacitor Cb and the diode D1 constitute a bootstrap 6. A boot voltage Vboot is generated at a node Nb at which the diode D1 is connected to the boot capacitor Cb.

The transistor drive circuit 1 includes a controller 2, a pre-driver 3, and a pre-driver 4. The pre-driver 3 causes the boot voltage Vboot to be applied to a gate of the NMOS transistor M1 so as to bring the NMOS transistor M1 to the on-state and causes a switch voltage Vsw generated at the node Nsw to be applied to the above-described gate so as to bring the NMOS transistor M1 to the off-state.

The pre-driver 4 causes a power supply voltage Vreg to be applied to a gate of the NMOS transistor M2 so as to bring the NMOS transistor M2 to the on-state and causes the ground potential to be applied to the above-described gate so as to bring the NMOS transistor M2 to the off-state.

In a case where the NMOS transistor M1 is in the off-state while the NMOS transistor M2 is in the on-state, the boot capacitor Cb is charged with the power supply voltage Vcc via the diode D1, and Boot Voltage Vboot=Vcc−Vf (Vf: a forward voltage of the diode DO is established. Thereafter, when the NMOS transistor M1 is in the on-state while the NMOS transistor M2 is in the off-state, Boot Voltage Vboot=Vin+Vcc−Vf is established, and the pre-driver 3 causes the boot voltage Vboot to be applied to the gate of the NMOS transistor M1 so as to bring the NMOS transistor M1 to the on-state.

The controller 2 controls driving of the pre-driver 3 and the pre-driver 4.

### First Embodiment

Herein, a description is given of a transistor drive circuit 1 according to a first embodiment. FIG. 2 is a diagram showing an internal configuration of a pre-driver 3 in the transistor drive circuit 1 according to the first embodiment. Here, an NMOS transistor M1 is designated as a transistor to be driven.

The pre-driver 3 shown in FIG. 2 includes PMOS transistors 31A, 31B, and 31C, an NMOS transistor 32, and switches SW1 to SW4. As for the number of PMOS transistors used, there is no limitation to the three PMOS transistors 31A, 31B, and 31C, and the number may be, for example, four or more.

The PMOS transistors 31A, 31B, and 31C are connected in parallel between an application terminal of a boot voltage Vboot and a node N3. Specifically, respective sources of the PMOS transistors 31A, 31B, and 31C are connected to the application terminal of the boot voltage Vboot. Respective drains of the PMOS transistors 31A, 31B, and 31C are connected to the node N3.

The node N3 is connected to a gate (a control terminal) of the NMOS transistor M1 and to a drain of the NMOS transistor 32. A source of the NMOS transistor 32 is connected to a node Nsw.

An output terminal of a controller 2 for outputting a gate signal G1 is directly connected to each of respective gates of the PMOS transistor 31A and the NMOS transistor 32. Furthermore, the switch SW1 is disposed between the above-described output terminal of the controller 2 and a gate of the PMOS transistor 31B. The switch SW2 is disposed between the above-described output terminal of the controller 2 and a gate of the PMOS transistor 31C.

The switch SW3 is disposed between the gate and the source of the PMOS transistor 31B. The switch SW4 is disposed between the gate and the source of the PMOS transistor 31C.

The controller 2 performs on/off control of the switches SW1 to SW4.

The controller 2 causes the gate signal G1 at a high level to be applied to each of the gates of the PMOS transistor 31A and the NMOS transistor 32 so as to bring the PMOS transistor 31A to an off-state and the NMOS transistor 32 to an on-state. On the other hand, the controller 2 causes the gate signal G1 at a low level to be applied to each of the gates of the PMOS transistor 31A and the NMOS transistor 32 so as to bring the PMOS transistor 31A to the on-state and the NMOS transistor 32 to the off-state.

Furthermore, in enabling the PMOS transistor 31B, the controller 2 brings the switch SW1 to an on-state and the switch SW3 to an off-state. As a result, on/off driving of the PMOS transistor 31B is performed based on a level of the gate signal G1. On the other hand, in disabling the PMOS transistor 31B, the controller 2 brings the switch SW1 to the off-state and the switch SW3 to the on-state. As a result, the PMOS transistor 31B has Vgs (a gate-source voltage) of 0 V, thus being brought to the off-state.

Furthermore, in enabling the PMOS transistor 31C, the controller 2 brings the switch SW2 to the on-state and the switch SW4 to the off-state. As a result, on/of driving of the PMOS transistor 31C is performed based on the level of the gate signal G1. On the other hand, in disabling the PMOS transistor 31C, the controller 2 brings the switch SW2 to the off-state and the switch SW4 to the on-state. As a result, the PMOS transistor 31C has Vgs of 0 V, thus being brought to the off-state.

The PMOS transistor 31A and an enabled one of the PMOS transistors 31B and 31C are in such a relation with the NMOS transistor 32 that when either of them is in the on-state, the other is brought to the off-state.

A current is supplied from the application terminal (a node Nb) of the boot voltage Vboot to the gate of the NMOS transistor M1 via the PMOS transistor 31A in the on-state and an enabled one of the PMOS transistors 31B and 31C, which is in the on-state, and thus the NMOS transistor M1 is turned on. Furthermore, a current is drawn out of the gate of the NMOS transistor M1 via the NMOS transistor 32 in the on-state, and thus the NMOS transistor M1 is turned off.

The controller 2 causes to temporally vary the number of parallel connected transistors that are enabled and capable of being turned on/off among the PMOS transistors 31A, 31B, and 31C.

More specifically, for example, when one on/off operation of the NMOS transistor M1 is defined as one switching operation, during a first predetermined number of times of switching operations, the PMOS transistors 31B and 31C are disabled, during a subsequent second predetermined number of times of switching operations, the PMOS transistor 31B is enabled while the PMOS transistor 31C is disabled, during a subsequent third predetermined number of times of switching operations, the PMOS transistors 31B and 31C are enabled, during subsequent another second predetermined number of times of switching operations, the PMOS transistor 31B is enabled while the PMOS transistor 31C is disabled, and during subsequent another first predetermined number of times of switching operations, the PMOS transistors 31B and 31C are disabled. In this case, the number of parallel connected transistors that are enabled changes from 1 to 2 to 3 to 2 to 1.

Accordingly, an on-resistance Ron between the application terminal of the boot voltage Vboot and the node N3 is caused to temporally vary, and thus a current that is supplied to the gate of the NMOS transistor M1 can be caused to temporally vary. Consequently, a rise time tr (a rise time tr of Vds) of the NMOS transistor M1 is temporally distributed, and thus it is possible to reduce EMI noise while suppressing an increase in switching loss. The above-described current corresponds to a circuit parameter contributing to the rise time tr of the MOS transistor M1.

Particularly, in a case where the transistor drive circuit 1 is applied to a vehicle, it can be expected to reduce EMI noise in a high frequency band (100 MHz or higher) equal to or higher than an FM band, in which there is a need for further suppression of the EMI noise as specified in the standards for on-vehicle devices. This effect can be obtained similarly also in embodiments below.

### Second Embodiment

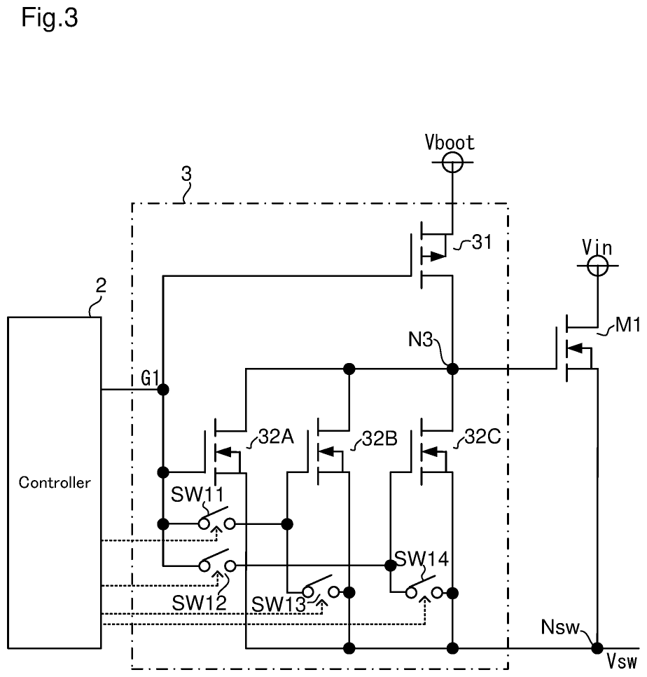

Next, a description is given of a transistor drive circuit 1 according to a second embodiment. FIG. 3 is a diagram showing an internal configuration of a pre-driver 3 in the transistor drive circuit 1 according to the second embodiment. Here, an NMOS transistor M1 is designated as a transistor to be driven.

The pre-driver 3 shown in FIG. 3 includes a PMOS transistor 31, NMOS transistors 32A, 32B, and 32C, and switches SW11 to SW14. As for the number of NMOS transistors used, there is no limitation to the three NMOS transistors 32A, 32B, and 32C, and the number may be, for example, four or more.

The PMOS transistor 31 is connected between an application terminal of a boot voltage Vboot and a node N3. Specifically, a source of the PMOS transistor 31 is connected to the application terminal of the boot voltage Vboot. A drain of the PMOS transistor 31 is connected to the node N3. The node N3 is connected to a gate of the NMOS transistor M1.

The NMOS transistors 32A, 32B, and 32C are connected in parallel between the node N3 and a node Nsw. Specifically, respective drains of the NMOS transistors 32A, 32B, and 32C are connected to the node N3. Respective sources of the NMOS transistor 32A, 32B, and 32C are connected to the node Nsw. The node Nsw is an application terminal of a switch voltage Vsw as a reference potential.

An output terminal of a controller 2 for outputting a gate signal G1 is directly connected to each of respective gates of the PMOS transistor 31 and the NMOS transistor 32A. Furthermore, the switch SW11 is disposed between the above-described output terminal of the controller 2 and a gate of the NMOS transistor 32B. The switch SW12 is disposed between the above-described output terminal of the controller 2 and a gate of the NMOS transistor 32C.

The switch SW13 is disposed between the gate and the source of the NMOS transistor 32B. The switch SW14 is disposed between the gate and the source of the NMOS transistor 32C.

The controller 2 performs on/off control of the switches SW11 to SW14.

The controller 2 causes the gate signal G1 at a high level to be applied to each of the gates of the PMOS transistor 31 and the NMOS transistor 32A so as to bring the PMOS transistor 31 to an off-state and the NMOS transistor 32A to an on-state. On the other hand, the controller 2 causes the gate signal G1 at a low level to be applied to each of the gates of the PMOS transistor 31 and the NMOS transistor 32A so as to bring the PMOS transistor 31 to the on-state and the NMOS transistor 32A to the off-state.

Furthermore, in enabling the NMOS transistor 32B, the controller 2 brings the switch SW11 to an on-state and the switch SW13 to an off-state. As a result, on/off driving of the NMOS transistor 32B is performed based on a level of the gate signal G1. On the other hand, in disabling the NMOS transistor 32B, the controller 2 brings the switch SW11 to the off-state and the switch SW13 to the on-state. As a result, the NMOS transistor 32B has Vgs of 0 V, thus being brought to the off-state.

Furthermore, in enabling the NMOS transistor 32C, the controller 2 brings the switch SW12 to the on-state and the switch SW14 to the off-state. As a result, on/off driving of the NMOS transistor 32C is performed based on the level of the gate signal G1. On the other hand, in disabling the NMOS transistor 32C, the controller 2 brings the switch SW12 to the off-state and the switch SW14 to the on-state. As a result, the NMOS transistor 32C has Vgs of 0 V, thus being brought to the off-state.

The NMOS transistor 32A and an enabled one of the NMOS transistors 32B and 32C are in such a relation with the PMOS transistor 31 that when either of them is in the on-state, the other is brought to the off-state.

A current is supplied from the application terminal of the boot voltage Vboot to the gate of the NMOS transistor M1 via the PMOS transistor 31 in the on-state, and thus the NMOS transistor M1 is turned on. Furthermore, a current is drawn out of the gate of the NMOS transistor M1 via the NMOS transistor 32A in the on-state and an enabled one of the NMOS transistors 32B and 32C, which is in the on-state, and thus the NMOS transistor M1 is turned off.

The controller 2 causes to temporally vary the number of parallel connected transistors that are enabled and capable of being turned on/off among the NMOS transistors 32A, 32B, and 32C.

More specifically, for example, when one on/off operation of the NMOS transistor M1 is defined as one switching operation, during a first predetermined number of times of switching operations, the NMOS transistors 32B and 32C are disabled, during a subsequent second predetermined number of times of switching operations, the NMOS transistor 32B is enabled while the NMOS transistor 32C is disabled, during a subsequent third predetermined number of times of switching operations, the NMOS transistors 32B and 32C are enabled, during subsequent another second predetermined number of times of switching operations, the NMOS transistor 32B is enabled while the NMOS transistor 32C is disabled, and during subsequent another first predetermined number of times of switching operations, the NMOS transistors 32B and 32C are disabled. In this case, the number of parallel connected transistors that are enabled changes from 1 to 2 to 3 to 2 to 1.

Accordingly, an on-resistance Ron between the node N3 and the node Nsw is caused to temporally vary, and thus a current drawn out of the gate of the NMOS transistor M1 can be caused to temporally vary. Consequently, a fall time tf (a fall time tf of Vds) of the NMOS transistor Ml is temporally distributed, and thus it is possible to reduce EMI noise while suppressing an increase in switching loss. The above-described current corresponds to a circuit parameter contributing to the fail time tf of the NMOS transistor M1.

### Third Embodiment

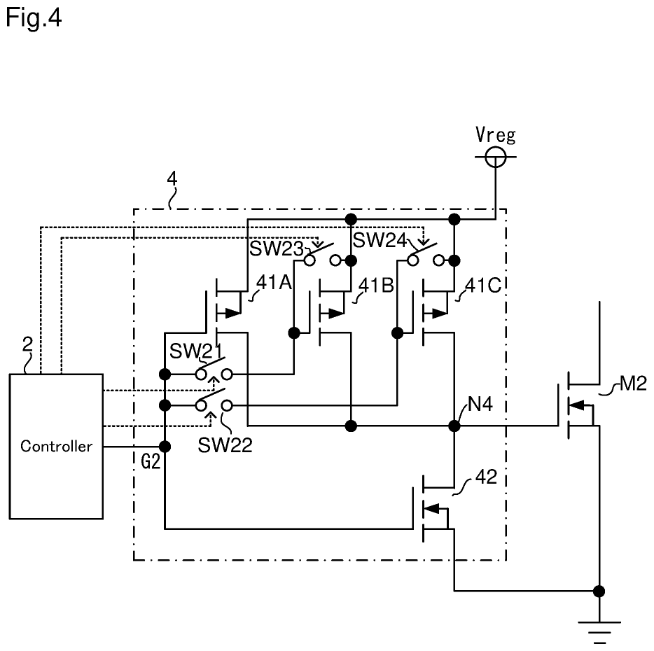

Next, a description is given of a transistor drive circuit 1 according to a third embodiment. FIG. 4 is a diagram showing an internal configuration of a pre-driver 4 in the transistor drive circuit 1 according to the third embodiment. Here, an NMOS transistor M2 is designated as a transistor to be driven.

The pre-driver 4 shown in FIG. 4 includes PMOS transistors 41A, 41B, and 41C, an NMOS transistor M42, and switches SW21 to SW24. As for the number of PMOS transistors used, there is no limitation to the three PMOS transistors 41A, 41B, and 41C, and the number may be, for example, four or more.

The pre-driver 4 according to this embodiment has a configuration similar to the earlier described configuration (FIG. 2) of the pre-driver 3 according to the first embodiment, in which the PMOS transistors 41A, 41B, and 41C of this embodiment correspond to the PMOS transistors 31A, 31B, and 31C of the first embodiment, respectively, the NMOS transistor 42 of this embodiment corresponds to the NMOS transistor 32 of the first embodiment, and the switches SW21 to SW24 of this embodiment correspond to the switches SW1 to SW4 of the first embodiment, respectively.

This embodiment is different from the first embodiment in the following respects. That is, respective drains of the PMOS transistors 41A, 41B, and 41C are connected to an application terminal of a power supply voltage Vreg. A node N4 at which the respective drains of the PMOS transistors 41A, 41B, and 41C are connected to a drain of the NMOS transistor 42 is connected to a gate of the NMOS transistor M2. A source of the NMOS transistor 42 is connected to an application terminal of a ground potential.

In a similar manner to that in the first embodiment, a controller 2 performs on/off control of the switches SW21 to SW24 so as to switch between enabled and disabled states of the PMOS transistors 41B and 41C. Based on a level of a gate signal G2 outputted from an output terminal of the controller 2, on/off driving of the PMOS transistor 41A and an enabled one of the PMOS transistors 41B and 41C is performed. Based on the level of the gate signal G2, on/off driving of the NMOS transistor 42 is also performed. The PMOS transistor 41A and an enabled one of the PMOS transistors 41B and 41C are in such a relation with the NMOS transistor 42 that when either of them is in an on-state, the other is brought to an off-state.

Further, in a similar manner to that in the first embodiment, the controller 2 causes to temporally vary the number of parallel connected transistors that are enabled and capable of being turned on/off among the PMOS transistors 41A, 41B, and 41C.

Accordingly, an on-resistance Ron between the application terminal of the power supply voltage Vreg and the node N4 is caused to temporally vary, and thus a current that is supplied to the gate of the NMOS transistor M2 can be caused to temporally vary. Consequently, a rise time tr (a rise time tr of Vds) of the NMOS transistor M2 is temporally distributed, and thus it is possible to reduce EMI noise while suppressing an increase in switching loss.

### Fourth Embodiment

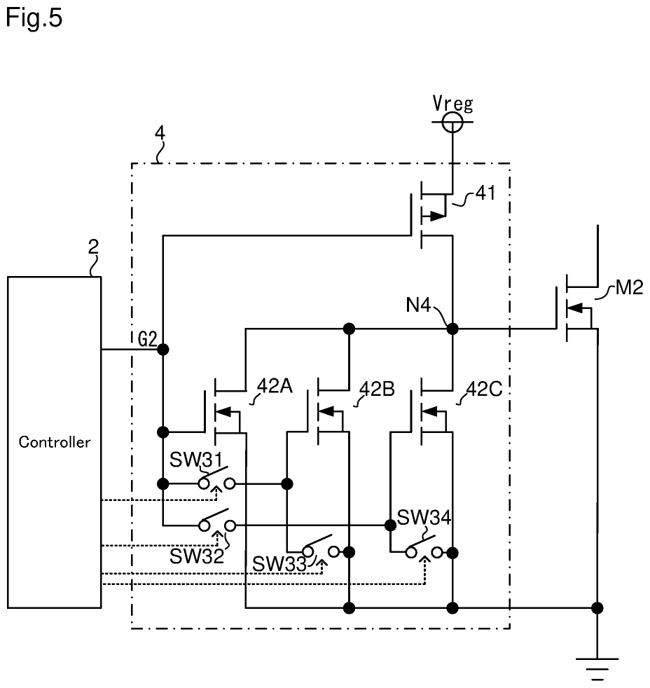

Next, a description is given of a transistor drive circuit 1 according to a fourth embodiment. FIG. 5 is a diagram showing an internal configuration of a pre-driver 4 in the transistor drive circuit 1 according to the fourth embodiment. Here, an NMOS transistor M2 is designated as a transistor to be driven.

The pre-driver 4 shown in FIG. 5 includes a PMOS transistor 41, NMOS transistors 42A, 42B, and 42C, and switches SW31 to SW34. As for the number of NMOS transistors used, there is no limitation to the three NMOS transistors 42A, 42B, and 42C, and the number may be, for example, four or more.

The pre-driver 4 according to this embodiment has a configuration similar to the earlier described configuration (FIG. 3) of the pre-driver 4 according to the second embodiment, in which the PMOS transistor 41 of this embodiment corresponds to the PMOS transistor 31 of the second embodiment, the NMOS transistors 42A, 42B, and 42C of this embodiment correspond to the NMOS transistors 32A, 32B, and 32C of the second embodiment, respectively, and the switches SW31 to SW34 of this embodiment correspond to the switches SW11 to SW14 of the second embodiment, respectively.

This embodiment is different from the second embodiment in the following respects. That is, a drain of the PMOS transistor 41 is connected to an application terminal of a power supply voltage Vreg. A node N4 at which the drain of the PMOS transistor 41 is connected to drains of the NMOS transistors 42A, 42B, and 42C is connected to a gate of the NMOS transistor M2. Respective sources of the NMOS transistors 42A, 42B, and 42C are connected to an application terminal of a ground potential (a reference potential).

In a similar manner to that in the second embodiment, a controller 2 performs on/off control of the switches SW31 to SW34 so as to switch between enabled and disabled states of the NMOS transistors 42B and 42C. Based on a level of a gate signal G2 outputted from an output terminal of the controller 2, on/off driving of the NMOS transistor 42A and an enabled one of the NMOS transistors 42B and 42C is performed. Based on the level of the gate signal G2, on/off driving of the PMOS transistor 41 is also performed. The NMOS transistor 42A and an enabled one of the NMOS transistors 42B and 42C are in such a relation with the PMOS transistor 41 that when either of them is in an on-state, the other is brought to an off-state.

Further, in a similar manner to that in the second embodiment, the controller 2 causes to temporally vary the number of parallel connected transistors that are enabled and capable of being turned on/off among the NMOS transistors 42A, 42B, and 42C.

Accordingly, an on-resistance Ron between the node N4 and the application terminal of the ground potential is caused to temporally vary, and thus a current drawn out of the gate of the NMOS transistor M2 can be caused to temporally vary. Consequently, a fall time tf (a fall time tf of Vds) of the NMOS transistor M2 is temporally distributed, and thus it is possible to reduce EMI noise while suppressing an increase in switching loss.

### Fifth Embodiment

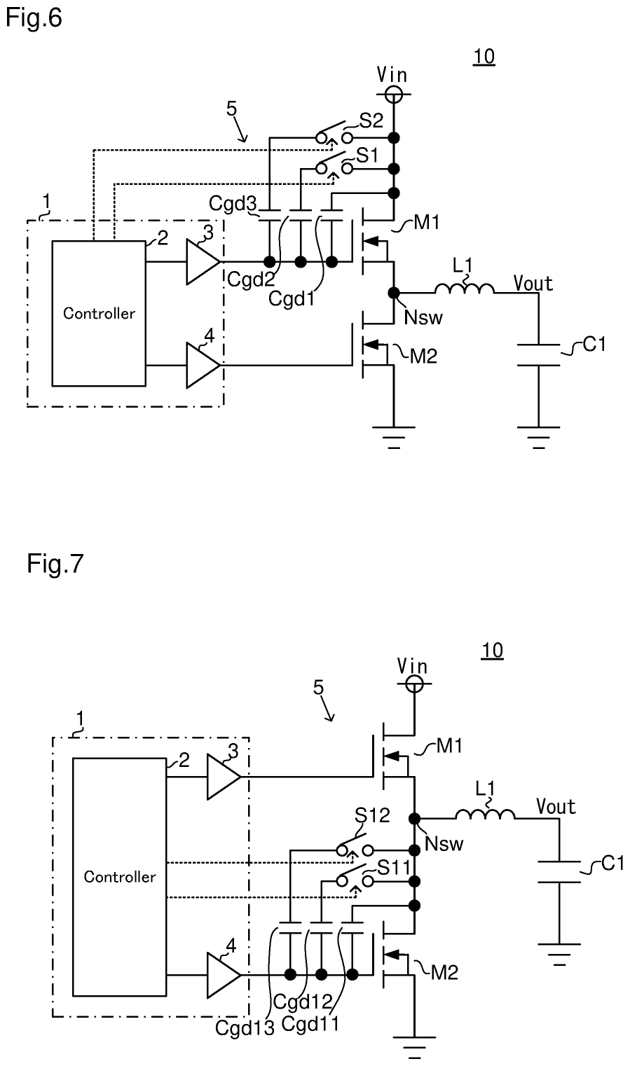

Next, a description is given of a fifth embodiment. FIG. 6 is a diagram showing a DC/DC converter 10 including a configuration of a switching circuit 5 according to the fifth embodiment. Here, an NMOS transistor M1 is designated as a transistor to be driven.

As shown in FIG. 6, the switching circuit 5 according to this embodiment includes a feedback capacitance Cgd1 that is a parasitic capacitance between a gate and a drain of the NMOS transistor M1 and feedback capacitances Cgd2 and Cgd3 that are connected between the gate and the drain of the NMOS transistor M1. As for the number of feedback capacitances other than the parasitic capacitance connected between the gate and the drain of the NMOS transistor M1, there is no limitation to the two feedback capacitances Cgd2 and Cgd3, and the number may be, for example, three or more.

One end of each of the feedback capacitances Cgd2 and Cgd3 is directly connected to the gate of the NMOS transistor M1. The other end of each of the feedback capacitances Cgd2 and Cgd3 is connected to the drain of the NMOS transistor M1 via a corresponding one of switches S1 and S2.

A controller 2 performs on/off control of the switches S1 and S2. When the switches S1 and S2 are in an on-state, the feedback capacitances Cgd2 and Cgd3 are enabled, and when the switches S1 and S2 are in an off-state, the feedback capacitances Cgd2 and Cgd3 are disabled.

In this embodiment, the controller 2 causes to temporally vary the number of parallel connected and enabled feedback capacitances between the gate and the drain of the NMOS transistor M1 among the feedback capacitances Cgd1, Cgd2, and Cgd3.

More specifically, for example, when one on/off operation of the NMOS transistor M1 is defined as one switching operation, during a first predetermined number of times of switching operations, the feedback capacitances Cgd2 and Cgd3 are disabled, during a subsequent second predetermined number of times of switching operations, the feedback capacitance Cgd2 is enabled while the feedback capacitance Cgd3 is disabled, during a subsequent third predetermined number of times of switching operations, the feedback capacitances Cgd2 and Cgd3 are enabled, during subsequent another second predetermined number of times of switching operations, the feedback capacitance Cgd2 is enabled while the feedback capacitance Cgd3 is disabled, and during subsequent another first predetermined number of times of switching operations, the feedback capacitances Cgd2 and Cgd3 are disabled. In this case, the number of parallel connected and enabled feedback capacitances changes from 1 to 2 to 3 to 2 to 1.

Accordingly, the feedback capacitance between the gate and the drain of the

NMOS transistor M1 is caused to temporally vary so that a rise time tr and a fall time tf of the NMOS transistor M1 is temporally distributed, and thus it is possible to reduce EMI noise while suppressing an increase in switching loss. The above-described feedback capacitance corresponds to a circuit parameter contributing to the rise time tr and the fall time tf of the NMOS transistor M1.

### Sixth Embodiment

Next, a description is given of a sixth embodiment. FIG. 7 is a diagram showing a DC/DC converter 10 including a configuration of a switching circuit 5 according to the sixth embodiment. Here, an NMOS transistor M2 is designated as a transistor to be driven.

As shown in FIG. 7, the switching circuit 5 according to this embodiment includes a feedback capacitance Cgd11 that is a parasitic capacitance between a gate and a drain of the NMOS transistor M2 and feedback capacitances Cgd12 and Cgd13 that are connected between the gate and the drain of the NMOS transistor M2. As for the number of feedback capacitances other than the parasitic capacitance connected between the gate and the drain of the NMOS transistor M2, there is no limitation to the two feedback capacitances Cgd12 and Cgd13, and the number may be, for example, three or more.

One end of each of the feedback capacitances Cgd12 and Cgd13 is directly connected to the gate of the NMOS transistor M2. The other end of each of the feedback capacitances Cgd12 and Cgd13 is connected to the drain of the NMOS transistor M2 via a corresponding one of switches S11 and S12.

A controller 2 performs on/off control of the switches S11 and S12. When the switches S11 and S12 are in an on-state, the feedback capacitances Cgd12 and Cgd13 are enabled, and when the switches S11 and S12 are in an off-state, the feedback capacitances Cgd2 and Cgd3 are disabled.

In this embodiment, the controller 2 causes to temporally vary the number of parallel connected and enabled feedback capacitances between the gate and the drain of the NMOS transistor M2 among the feedback capacitances Cgd11, Cgd12, and Cgd13.

More specifically, for example, when one on/off operation of the NMOS transistor M2 is defined as one switching operation, during a first predetermined number of times of switching operations, the feedback capacitances Cgd12 and Cgd13 are disabled, during a subsequent second predetermined number of times of switching operations, the feedback capacitance Cgd12 is enabled while the feedback capacitance Cgd13 is disabled, during a subsequent third predetermined number of times of switching operations, the feedback capacitances Cgd12 and Cgd13 are enabled, during subsequent another second predetermined number of times of switching operations, the feedback capacitance Cgd12 is enabled while the feedback capacitance Cgd13 is disabled, and during subsequent another first predetermined number of times of switching operations, the feedback capacitances Cgd12 and Cgd13 are disabled. In this case, the number of parallel connected and enabled feedback capacitances changes from 1 to 2 to 3 to 2 to 1.

Accordingly, the feedback capacitance between the gate and the drain of the NMOS transistor M2 is caused to temporally vary so that a rise time tr and a fall time tf of the NMOS transistor M2 is temporally distributed, and thus it is possible to reduce EMI noise while suppressing an increase in switching loss.

### Seventh Embodiment

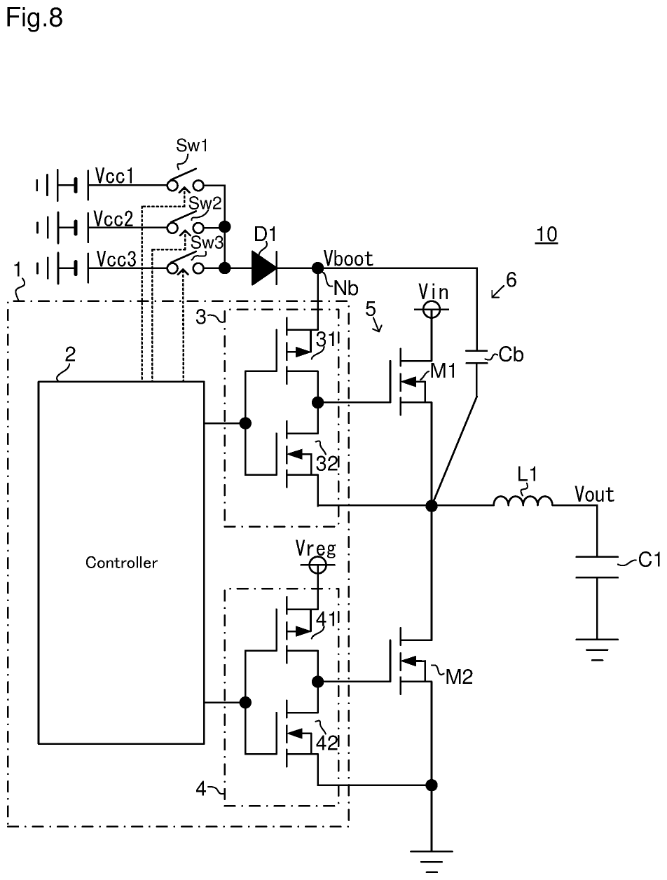

FIG. 8 is a diagram showing a configuration of a DC/DC converter 10 according to a seventh embodiment. Here, an NMOS transistor M1 is designated as a transistor to be driven. In the DC/DC converter 10 shown in FIG. 8, switches Sw1 to Sw3 are provided in a bootstrap 6.

The switch Sw1 is disposed between an application terminal of a predetermined power supply voltage Vcc1 and an anode of a diode D1. The switch Sw2 is disposed between an application terminal of a predetermined power supply voltage Vcc2 and the anode of the diode D1. The switch Sw3 is disposed between an application terminal of a predetermined power supply voltage Vcc3 and the anode of the diode D1. For example, a magnitude relationship among the power supply voltages Vcc1 to Vcc3 is expressed by Vcc1<Vcc2<Vcc3. As for the number of power supply voltages, there is no limitation to the three power supply voltages Vcc1 to Vcc3, and the number may be, for example, four or more.

A controller 2 performs on/off control of the switches Sw1 to Sw3.

Furthermore, in this embodiment, a pre-driver 3 includes a PMOS transistor 31 and an NMOS transistor 32. A node Nb is connected to a source of the PMOS transistor 31, and thus a boot voltage Vboot is applied to the source.

In this embodiment, the controller 2 causes to temporally vary the boot voltage Vboot at a time of turning on the NMOS transistor M1.

More specifically, for example, when one on/off operation of the NMOS transistor M1 is defined as one switching operation, during a first predetermined number of times of switching operations, the switch Sw1 is brought to an on-state while the switches Sw2 and Sw3 are brought to an off-state, during a subsequent second predetermined number of times of switching operations, the switch Sw2 is brought to the on-state while the switches Sw1 and Sw3 are brought to the off-state, during a subsequent third predetermined number of times of switching operations, the switch Sw3 is brought to the on-state while the switches Sw1 and Sw2 are brought to the off-state, during subsequent another second predetermined number of times of switching operations, the switch Sw2 is brought to the on-state while the switches Sw1 and Sw3 are brought to the off-state, and during subsequent another first predetermined number of times of switching operations, the switch Sw1 is brought to the on-state while the switches Sw2 and Sw3 are brought to the off-state.

Accordingly, the boot voltage Vboot at the time of turning on the NMOS transistor M1 changes from Vin+Vcc1−Vf to Vin+Vcc2−Vf to Vin+Vcc3−Vf to Vin+Vcc2−Vf to Vin+Vcc1−Vf.

Herein, an on-resistance Ron of the PMOS transistor 31 is a function of Vgs of the PMOS transistor 31, and thus when the boot voltage Vboot temporally varies, the on-resistance Ron of the PMOS transistor 31 also temporally varies. Consequently, a current that is supplied to a gate of the NMOS transistor M1 via the PMOS transistor 31 varies, and thus a rise time tr of the NMOS transistor Ml is temporally distributed. Accordingly, it is possible to reduce EMI noise while suppressing an increase in switching loss.

In this embodiment, the boot voltage Vboot is caused to vary, thus causing an on-resistance of the NMOS transistor M1 also to vary. However, when, for example, the boot voltage Vboot is caused to vary sinusoidally, it is possible to obtain, as an average of the on-resistance of the NMOS transistor M1, a value corresponding to an average of a sinusoidal wave.

Furthermore, with regard to a power supply voltage Vreg that is supplied to a pre-driver 4, the controller 2 may cause to temporally vary the power supply voltage Vreg at a time of turning on an NMOS transistor M2. Accordingly, a rise time tr of the NMOS transistor M2 can be temporally distributed.

### Regarding FFT Analysis

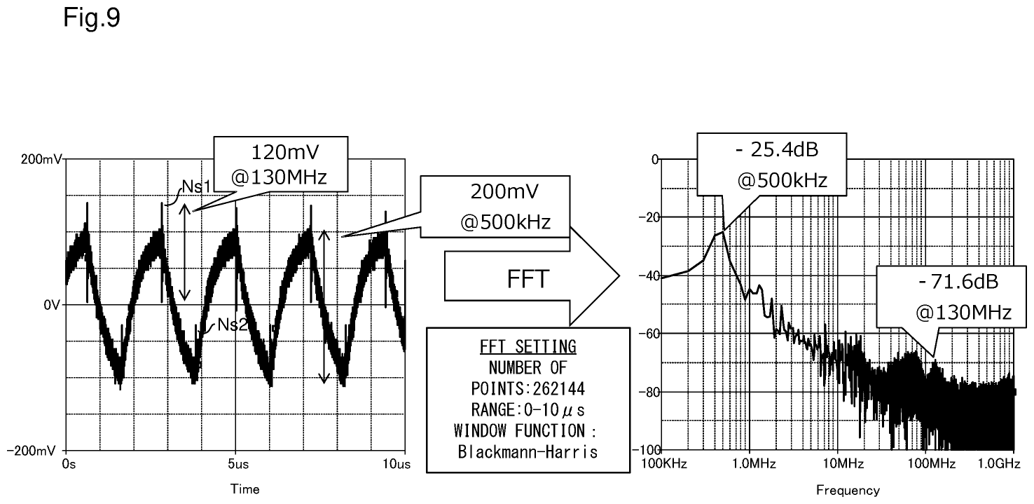

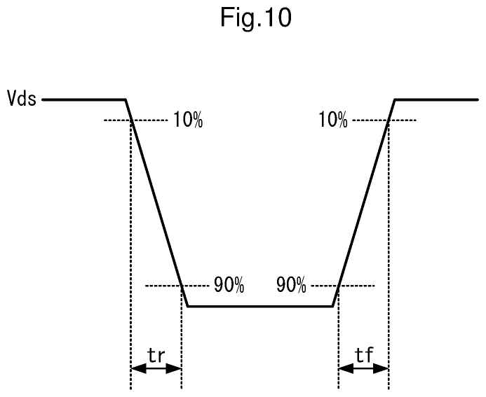

Herein, FIG. 9 shows, in a left drawing thereof, an example of a ripple voltage waveform generated in the input voltage Vin in the DC/DC converter 10 (FIG. 1) in a case where the input voltage Vin=12 V and the output voltage Vout=5 V. The input voltage Vin is supplied from an unshown battery, and an unshown capacitor is connected to an output terminal of the battery.

As shown in the left drawing of FIG. 9, when the NMOS transistor M1 is turned on, the above-described capacitor is discharged to decrease the input voltage Vin. Thereafter, when the NMOS transistor M1 is turned off, the above-described capacitor is charged to increase the input voltage Vin. These operations are repeatedly performed, and thus a 500 kHz waveform with an amplitude of 200 mV is generated in a ripple of the input voltage Vin. Furthermore, at this time, noise Ns1 is generated at a time of turning on the NMOS transistor M1, while noise Ns2 is generated at a time of turning off the NMOS transistor M1. The noise Ns1 has a 130 MHz waveform with an amplitude of 120 mV.

FIG. 9 shows, in a right drawing thereof, a result of an FFT (fast Fourier transform) analysis of the waveform shown in the left drawing thereof. As shown in the right drawing of FIG. 9, a spectral value at 500 kHz is −25.4 dB, and a spectral value at 130 MHz is −71.6 dB.

As shown in the left drawing of FIG. 9, the 500 kHz waveform has an amplitude of 200 mV, and thus an RMS value thereof is expressed by 200 mV/(2×√2)=70.7 mV, so that there is obtained a spectral value expressed by 20×log(70.7 mV)=−23 dB, which substantially agrees with the result shown in the right drawing of FIG. 9. However, the 130 MHz waveform has an amplitude of 120 mV, and thus an RMS value thereof is expressed by 120 mV/(2×√2)=42.4 mV, so that there is obtained a spectral value expressed by 20×log(42.4 mV)=—27 dB, which does not agree with the result shown in the right drawing of FIG. 9.

Herein, as shown in the left drawing of FIG. 9, within an FFT range of up to 10 μs, the noise Ns 1 at 130 MHz appears five times for a period of time expressed by 1/130 MHz×5=38 ns. Consequently, a probability of appearance thereof is expressed by 38 ns/10 μs=0.0038=−48.4 dB. Accordingly, a spectral value in view of the probability of appearance is expressed by −27 dB +(−48 dB)=−75 dB which substantially agrees with the result shown in the right drawing of FIG. 9.

Consequently, as in the forgoing embodiments, the rise time tr and the fall time tf are temporally distributed, and thus a probability of appearance of noise at the same frequency is decreased, so that it is possible to reduce a spectral value of the noise.

### Other Modifications

While the foregoing has described the embodiments of the present invention, various modifications can be made to the embodiments without departing from the spirit of the present invention.

For example, the foregoing embodiments can be implemented in any combination thereof as long as there is no inconsistency.

Furthermore, in the switching circuit 5 in each of the foregoing embodiments, a PMOS transistor may be used in place of the NMOS transistor M1 on a high side. In this case, it is sufficient to use a voltage lower than the input voltage Yin as a power supply voltage of the pre-driver 3, and thus there is no need to generate the power supply voltage of the pre-driver 3 by a bootstrap or the like.

Furthermore, the transistor drive circuit according to the present invention is not limited to a step-clown type DC/DC converter and is applicable also to switching power supply circuits including various types of DC/DC converters such as step-up type, step-up and step-down type, non-isolated, and isolated DC/DC converters and a DC/AC converter (an inverter) and further to other types of circuits than power supply circuits.

Furthermore, a transistor to be driven by the transistor drive circuit according to the present invention is not limited to a MOSFET and may be, for example, an IGBT.

### INDUSTRIAL APPLICABILITY

The invention disclosed in the present description is usable to drive various types of transistors.

### REFERENCE SIGNS LIST

1 transistor drive circuit
2 controller
3 pre-driver
4 pre-driver
5 switching circuit
6 bootstrap
10 DC/DC converter
M1, M2 NMOS transistor
L1 inductor
C1 output capacitor
Cb boot capacitor
D1 diode
31A to 31C PMOS transistor
32 NMOS transistor
SW1 to SW4 switch
31 PMOS transistor
32A to 32C NMOS transistor
SW11 to SW14 switch
41A to 41C PMOS transistor
42 NMOS transistor
SW21 to SW24 switch
41 PMOS transistor
42A to 42C NMOS transistor
SW31 to SW34 switch
Cgd1 to Cgd3 feedback capacitance

S2 switch
Cgd11 to Cgd13 feedback capacitance
S11, S12 switch
Sw1 to Sw3 switch

1. A transistor drive circuit that drives a transistor to be driven, the transistor drive circuit comprising:
a controller that performs control to cause to temporally vary a circuit parameter contributing to a rise time or a fall time of the transistor to be driven.

2. The transistor drive circuit according to claim 1, wherein
the circuit parameter is a current that is supplied to a control terminal of the transistor to be driven.

3. The transistor drive circuit according to claim 2, further comprising:
a pre-driver that includes a first transistor portion through which the current flows,
wherein the controller causes to temporally vary an on-resistance of the first transistor portion.

4. The transistor drive circuit according to claim 3, wherein
the first transistor portion includes a plurality of first transistors that are connected in parallel between an application terminal of a power supply voltage and the control terminal, and
the controller causes to temporally vary a number of parallel connected first transistors that are in an enabled state and capable of being turned on/off among the plurality of first transistors.

5. The transistor drive circuit according to claim 4, wherein
each of the first transistors is a PMOS transistor, and
the pre-driver includes:
a first switch that is disposed between an application terminal of a gate signal and a gate of the each of the first transistors; and
a second switch that is disposed between the gate and a source of the each of the first transistors.

6. The transistor drive circuit according to claim 1, wherein
the circuit parameter is a current drawn out of a control terminal of the transistor to be driven.

7. The transistor drive circuit according to claim 6, further comprising:
a pre-driver that includes a second transistor portion through which the current flows,
wherein the controller causes to temporally vary an on-resistance of the second transistor portion.

8. The transistor drive circuit according to claim 7, wherein
the second transistor portion includes a plurality of second transistors that are connected in parallel between the control terminal and an application terminal of a reference potential, and
the controller causes to temporally vary a number of parallel connected second transistors that are in an enabled state and capable of being turned on/off among the plurality of second transistors.

9. The transistor drive circuit according to claim 8, wherein
each of the second transistors is an NMOS transistor, and
the pre-driver includes:
a third switch that is disposed between an application terminal of a gate signal and a gate of the each of the second transistors; and
a fourth switch that is disposed between the gate and a source of the each of the second transistors.

10. The transistor drive circuit according to claim 1, wherein
the circuit parameter is a feedback capacitance of the transistor to be driven.

11. The transistor drive circuit according to claim 10, wherein
the controller causes to temporally vary a number of parallel connected feedback capacitances including a first feedback capacitance as a parasitic capacitance of the transistor to be driven and an enabled one of at least one second feedback capacitance other than the first feedback capacitance.

12. The transistor drive circuit according to claim 11, wherein
the controller controls a fifth switch for switching between enabled and disabled states of the at least one second feedback capacitance.

13. The transistor drive circuit according to claim 3, wherein
the first transistor portion includes a PMOS transistor, and
the controller causes to temporally vary a power supply voltage of the pre-driver.

14. The transistor drive circuit according to claim 13, wherein
the power supply voltage is a boot voltage generated by a bootstrap.

15. The transistor drive circuit according to claim 14, wherein
the controller causes to temporally vary a voltage that is applied to an anode of a diode included in the bootstrap.

16. A switching circuit, comprising:
the transistor drive circuit according to claim 1; and
the transistor to be driven.

17. The switching circuit according to claim 16, wherein
the transistor to be driven is an NMOS transistor.

18. The switching circuit according to claim 17, further comprising:
an NMOS transistor on a low potential side that is connected in series with the transistor to be driven on a high potential side.

19. switching power supply circuit, comprising:
the switching circuit according to claim 1.
